(19) United States
(12) Patent Application Publication
(10) Pub. No.: US 2008/0041443 A1
(43) Pub. Date: Feb. 21, 2008

(54) Thinned solar cell

(75) Inventors: Dan O'Connell, Wailuku, HI (US); Terry Born, Wailuku, HI (US)

Correspondence Address: MORGAN LEWIS & BOCKIUS LLP, 1111 PENNSYLVANIA AVENUE NW, WASHINGTON, DC, 20004, US

(73) Assignee: hNUPHOTONICS

(21) Appl. No.: 11/889,369

(22) Filed: Aug. 13, 2007

Related U.S. Application Data
(60) Provisional application No. 60/837,934, filed on Aug. 16, 2006.

(51) Int. Cl. H01L 31/04; H01L 31/0216

(52) U.S. Cl. 136/256; 136/252; 136/259; 136/261

(57) ABSTRACT

The present invention relates to a solar or photovoltaic cell wherein the thickness of the photovoltaic substrate is reduced such that the efficiency of the photovoltaic cell is about 100% greater than a typical photovoltaic cell. The solar cell can also include a cold plate located adjacent to the solar cell to remove heat from the solar cell.

### RELATED U.S. APPLICATION

This application claims priority to U.S. Provisional Application 60/837,934, filed Aug. 16, 2006.

### INCORPORATION-BY-REFERENCE OF MATERIAL SUBMITTED ON A COMPACT DISC

Not applicable.

### BACKGROUND OF THE INVENTION

1. Field of the Invention

The present invention relates to a photovoltaic cell, and more particularly to a Silicon-based photovoltaic cell with reduced thickness and enhanced efficiency.

2. Description of Related Art

A solar cell is a semiconductor device that converts incident photons from the sun (solar radiation) into useable electrical power. The general term for a solar cell is a Photo-Voltaic (PV) cell. The output of a conventional PV solar cell is limited to approximately 10% efficiency and as much as 15% to 20% in high end single crystal silicon solar panels. Single crystal silicon PV cells have a higher efficiency than polycrystalline silicon; however, they are considerably more expensive.

The sun delivers approximately 1,000 Watts of light energy per square meter on the surface of the earth near the equator at 12 noon. Existing solar cells (or solar panels) used for electrical power generation generate electricity by the photo-electric effect. A photon of energy, which equals h ν (where h is Plank's constant and ν is frequency of light), is incident on a semi-conductor material such as doped silicon, producing a free electron that is drawn away by an external circuit, therefore generating an electrical current. The silicon substrate (having 4 valence electrons available for covalent bonding) typically contains two layers that are doped with atoms containing 3 or 5 valence electrons (III-V) such as Boron and Phosphorus for example. The junction between these two doped layers forms what is referred to as a p-n junction. The p region contains an excess of holes, or atoms, lacking an outer valence electron, and the n region contains atoms that have an excess valence electron. A depletion region is established where excess electrons and excess holes are located on opposite sides of the depletion region boundary. When an incident photon impinges on the silicon substrate it must travel deep enough into the n-doped material to reach the vicinity of the depletion region, where it interacts with atoms containing excess electrons. Otherwise, excited electrons recombine with holes such that the excited electron is not swept into the conduction band by the internal electric field. The incident photon transfers energy to the atom, which raises the energy state of the electron such that it crosses the bandgap into the conduction band and is drawn away as current by the electric field established. Typical solar panels exhibit low efficiencies, on the order of 15%, and the best technology on the market reaches 20% at a large cost to the consumer.

The low efficiency is attributed to the properties of silicon and the energy bandgap. Short wavelength photons (blue light) have higher energy than long wavelength photons (red light) and get absorbed at shallow depths in the host silicon substrate and are converted into heat. These photons never reach the depletion region and are absorbed by the material and contribute to lost energy. “Red” photons travel deep into the material and do not have sufficient energy to raise an electron to cross the bandgap. These photons are transmitted deeper into the material or pass directly through and contribute to lost energy or contribute to heating the material. Therefore, only a narrow portion of the available solar radiation is utilized by existing PV solar cell technology. Research laboratories are applying multiple doping layers in order to trap or absorb photons in successive layers corresponding to longer wavelengths (or lower energy), therefore increasing the spectrum of absorbed solar radiation that contributes to useable electricity. These materials include Gallium Arsenide (GaAs), Indium Selenide (InSe) as well as others. These multi-layer materials are several times more expensive than first generation Si PV material. In addition these multi-layer solar cells are limited to 30% efficiency at the moment.

U.S. Pat. No. 6,974,976 discloses a method of manufacturing improved thin-film solar cells by sputtering. The solar cell comprises a copper indium gallium diselenide absorber layer. This type of solar cell is much more expensive than the traditional Silicon-based solar cells.

U.S. Pat. No. 6,692,985 discloses a solar cell substrate with thin film polysilicon. This type of cell does not use the more expensive gallium or indium-based materials. It does, however, rely upon the addition of additional layers of material, and thus is relatively expensive to manufacture.

Accordingly, there is a need to improve the efficiency of Si-based photovoltaic cells, and do so at a low cost.

### SUMMARY

The present invention is therefore directed to a photovoltaic cell that substantially obviates one or more of the problems due to the limitations and disadvantages of the related art.

An object of the invention relates to a photovoltaic cell comprising a substrate, wherein the thickness of the outer layer of the substrate is reduced such that the efficiency of the photovoltaic cell is about 100% greater than that of a photovoltaic cell in which the outer layer of the photovoltaic cell is not reduced. In one embodiment, the substrate comprises silicon. In another embodiment, the photovoltaic cell further comprises a temperature controlled cold plate adjacent to the cell. In yet another embodiment, the photovoltaic cell comprises an anti-reflective coating adjacent to the photovoltaic cell to remove heat therefrom.

In another embodiment, the invention relates to a method of increasing the efficiency of a photovoltaic cell comprising a substrate by at least 100%, the method comprising reducing the thickness of the outer layer of the substrate.

The thinned solar cell (TSC) can increases the efficiency of existing solar cell technology by 100% or greater. The cells of the TSC invention are a low cost technique applied to solar cell technology that raises the efficiency of existing solar cells. The TSC invention will increase the efficiency of existing solar cell technology resulting in greater electrical output at a lower cost than other techniques that utilize expensive materials and processes.

The TSC invention is significant in that it may increase the power output of solar panels at a lower cost, making them practical for all homes (or any other application). Existing solar cells used for individual homes take up the entire roof and are very expensive which limits their use.

The TSC invention has the following benefits over existing technology:
1. a reduction in size of the solar cell to achieve existing power levels;
2. an increase in the output of solar cells of equivalent size;
3. a great reduction in the cost of solar cell systems such that they are available to the majority of homeowners.

When combined with the “solar condenser” invention, which is disclosed in a concurrently filed provisional application, the output of existing solar cell technology can be increased by an additional 100% to 200%.

The thinned solar cell invention increases the quantum efficiency of solar cells (of many types, including, but not limited to Si-based) and the “solar condenser” invention increases the amount of light collected by a given solar cell (of any type or manufacturer) by a factor of 2, 3, 4, etc. (Note: The amount of additional current output from the “Solar Condenser” invention is limited by the saturation threshold in the photo-voltaic substrate).

Additional features and advantages of the invention will be set forth in the description which follows, and will be apparent, in part, from the description, or may be learned by practice of the invention. The objectives and other advantages of the invention will be realized and attained by the structure particularly pointed out in the written description and claims hereof, as well as the appended drawings.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

FIG. 1 is a graphical depiction of a normalized solar spectrum

FIG. 2 is a general diagram of the thinned solar cell capturing a larger portion of the solar spectrum.

### DETAILED DESCRIPTION OF THE INVENTION

The “Thinned Solar Cell” invention described herein makes use of existing Si-based solar cells and increases the efficiency up to 90% or greater for peak absorption. The outer layer of silicon based solar cell can be reduced in thickness in order to bring the depletion region or p-n junction closer to the surface where desired photon absorption occurs. Photon absorption in this region converts incident photons into useable electrons in the form of electric current. The thickness of the outer layer of PV material can be reduced to within the diffusion depth of an incident photon. The thickness of the outer layer can be designed to maximize the spectral range of absorbed photons that contribute to useable electrical power.

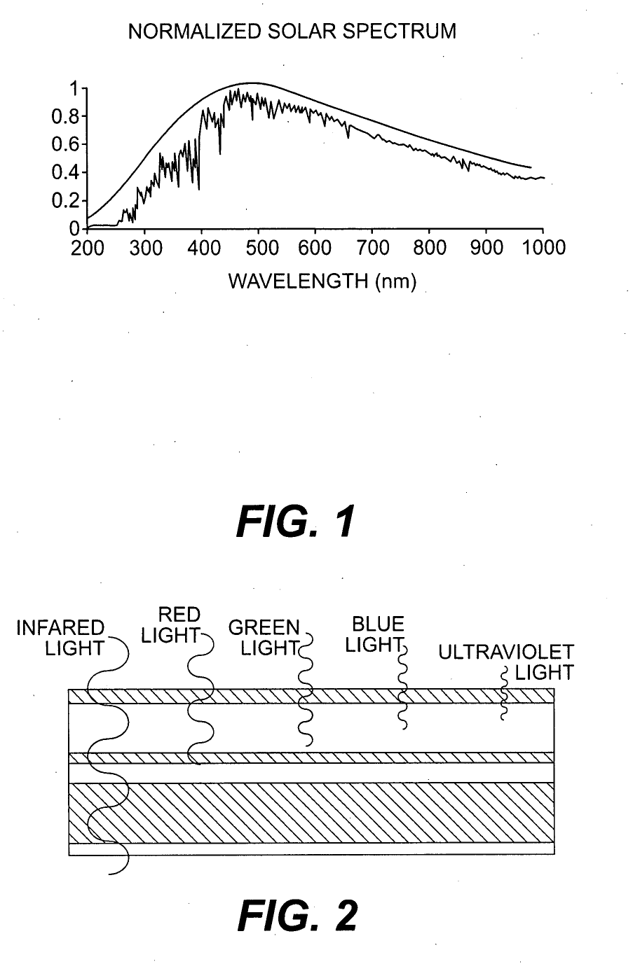

FIG. 1 shows the relative amount of energy available from the sun over a broad spectral range from 200 nm to 1,100 nm. The majority of Ultra-Violet (UV) light below approximately 300 nm is absorbed by the earth's atmosphere. Near-Infrared (NIR) light beyond 1,100 nm is not absorbed by silicon based photo-voltaic (PV) material. FIG. 1 shows the measured solar radiation from the earth as well as the calculated (approximated) energy using Planks Blackbody equation, which states that the spectral radiance of an object can be calculated based on the temperature of the object. Therefore, it is possible to estimate the amount of solar energy available within a particular bandwidth or wavelength range by integrating the Plank equation using the desired lower and upper wavelength limits. It can be observed in FIG. 1 that the peak irradiance from the sun (˜6,000 Kelvin) is near the green wavelength.

A large portion of the available solar radiation is not utilized by existing PV solar cell technology. An embodiment of the thinned solar cell invention consists of a solar cell that is reduced in thickness such that a greater portion of the solar spectrum reaches the vicinity of the depletion region within a diffusion length and is not absorbed at an unusable location in the material. The thinned solar cell invention can integrate a temperature controlled cold plate to reduce the operating temperature of the solar cell substrate.

FIG. 2 shows that by reducing the thickness of the outer layer of the PV material, a larger percentage of photons are able to reach the vicinity of the depletion region established by the doped layers within the silicon and contribute to useable electricity. In FIG. 2, A represents an anode, B represents a P doped silicon layer, C represents a depletion region, D represents an N doped silicon layer, E represents a silicon substrate layer and F represents a cathode.

The thinned solar cell can then be coated with an anti-reflection coating to reduce the number of lost photons resulting from reflections at the surface of the material. These surface losses are due to the large Fresnel reflections at the boundary between air (index of refraction n=1.0) and silicon (index n=3.6). An ideal anti-reflection coating would have an index of refraction equal to the square root of the substrate index or n=1.9. An example of an anti-reflection coating applied to silicon can include hafnium dioxide, titanium dioxide or silicon nitride. Existing solar cells are often coated to reduce surface reflections. Here the anti-reflection coating is applied to a thinned solar cell.

Typically PV material used as a solar cell for power generation is used in forward bias configuration. The photo-generated current is linearly proportional to the number of incident photons over a large range. Noise electrons (or noise current) are also generated which do not contribute to useable photo-generated current, therefore limiting the output of a solar panel. Some of the noise current is generated when the material operates at elevated temperatures. The thinned solar cell includes a cooling layer that consists of a semi-conductor Thermal Electric (TE) cooling device of the Peltier type, liquid or any other cooling technique to minimize noise current such as thermally generated electrons typically associated with Johnson noise or resistive heating. The cooling layer or cooling jacket is bonded to (or part of) the electrical backplane of the photo-voltaic substrate. The cooling system will lower the operating temperature of the solar cell using a portion of the generated electrical output, therefore lowering the noise and ultimately increasing the efficiency of the solar cell.

The thickness of the substrate can be reduced using chemical, mechanical or any other means of etching (liquid or dry), grinding or polishing (e.g., chemical, mechanical, chemo-mechanical, ion bombardment). This will increase the efficiency of existing solar cells by 100% or greater.

The process of thinning doped silicon has been successfully applied to Charge Coupled Devices (CCD) imaging detector arrays where greater than 90% peak Quantum Efficiency (QE) has been achieved. The electrical biasing of the silicon material in a CCD is not equivalent to that of a solar cell which is typically “forward biased” for electrical power generation. A solar cell would not produce a low noise imaging sensor. Noise in a solar cell arises from electrons that are generated in the material but do not contribute to useable electricity. Schott and Johnson noise limit amount of photo-generated electrons that contributes to useable current. Therefore, thinning a solar cell may not have the gain or increased efficiency to that experienced in CCD imaging sensors. However by thinning existing solar cells it is possible in increase the percentage of incident photons that are absorbed at the desired depth in the doped silicon material therefore contributing to larger current densities and increasing the efficiency of existing solar cells at a low cost.

As the present invention may be embodied in several forms without departing from the spirit or essential characteristics thereof, it should also be understood that the above-described embodiments are not limited by any of the details of the foregoing description, unless otherwise specified, but rather should be construed broadly within its spirit and scope as defined in the appended claims, and therefore all changes and modifications that fall within the metes and bounds of the claims, or equivalence of such metes and bounds are therefore intended to be embraced by the appended claims.

1. A photovoltaic cell comprising a substrate, wherein the thickness of the outer layer of the substrate is reduced such that the efficiency of the photovoltaic cell is about 100% greater than that of a photovoltaic cell in which the outer layer of the photovoltaic cell is not reduced.

2. The photovoltaic cell of claim 1, wherein substrate comprises silicon and doped silicon layers.

3. The photovoltaic cell of claim 1, further comprising a temperature controlled cold plate adjacent to the photovoltaic cell to remove heat therefrom.

4. The photovoltaic cell of claim 3, wherein the cold plate comprises a semi-conductor Thermal Electric cooling device of the Peltier type.

5. The photovoltaic device of claim 1, further comprising an anti-reflective coating.

6. The photovoltaic device of claim 5, wherein the anti-reflective coating comprises hafnium dioxide, titanium dioxide, silicon dioxide, or mixtures thereof.

7. The photovoltaic device of claim 5, wherein the anti-reflective coating has a refractive index of about n=1.9.

8. The photovoltaic device of claim 1, wherein the thickness of the outer layer of photovoltaic substrate is reduced by grinding.

9. The photovoltaic device of claim 1, wherein the thickness of the outer layer is reduced by chemical etching.

10. The photovoltaic device of claim 1, wherein the thickness of the outer layer is reduced by ion bombardment.

11. A method of increasing the efficiency of a photovoltaic cell comprising a substrate by at least 100%, the method comprising reducing the thickness of the outer layer of the substrate.

12. The method of claim 11, wherein the thickness of the outer layer of the substrate is reduced by etching the substrate.

13. The method of claim 11, wherein the thickness of the outer layer of the substrate is reduced by grinding the substrate.

14. The method of claim 11, wherein the thickness of the outer layer of the substrate is reduced by ion bombardment of the substrate.

15. The method of claim 11, further comprising adding a cooling device adjacent to the photovoltaic cell to cool the cell during use.

16. The method of claim 15, wherein the cooling device is a Peltier cooler.

17. The method of claim 11, further comprising adding a reflective coating to the photovoltaic cell after the thickness of the outer layer of substrate is reduced.
